(19) United States
(12) Patent Application Publication
(10) Pub. No.: US 2023/0385679 A1
(43) Pub. Date: Nov. 30, 2023

(54) POLYNOMIAL-TIME LINEAR CROSS-ENTROPY BENCHMARKING

(71) Applicant: Alibaba (China) Co., Ltd., Hangzhou (CN)

(72) Inventors: Jiachen HUANG, San Mateo, CA (US); Dawei DING, San Diego, CA (US); Jianxin CHEN, Kirkland, WA (US)

(21) Appl. No.: 17/804,664

(22) Filed: May 31, 2022

(51) Int. Cl. G06N 10/70; G06N 10/20

(52) U.S. Cl. CPC G06N 10/70; G06N 10/20

(57) ABSTRACT

Systems and methods are disclosed for benchmarking a set of quantum gates. Consistent with disclosed embodiments, a benchmarking method can include obtaining a sequence of M quantum gates from a group of quantum gates according to a probability distribution. The quantum gates in the group can be capable of polynomial-time classical simulation. The method can further include obtaining an outcome measure by applying the sequence of M quantum gates to N qubits of a quantum computing device and obtaining a probability of obtaining the outcome value given the application of the selected sequence of quantum gates. The probability can be obtained using classical simulation of the selected sequence of quantum gates. A fidelity benchmark for the M quantum gates can be generated based at least in part on the obtained probability.

### TECHNICAL FIELD

The present disclosure generally relates to quantum computing, and more particularly, to a benchmarking protocol that uses quantum gates suitable for classical simulation in polynomial time.

### BACKGROUND

Quantum computing can address classically intractable computational problems. However, existing quantum computational devices are limited by various sources of error and imprecision. Benchmarking can be used to determine the fidelity of a set of gates implemented on a quantum computational device. Conventional linear cross-entropy benchmarking (XEB) can be performed using shallow quantum circuits but is unsuitable for benchmarking more complicated quantum circuits. Polynomial-time linear cross-entropy benchmarking (PXEB) techniques may enable identification of gate sets or quantum computational devices having superior fidelity, thus supporting the development of quantum computing.

### SUMMARY

The disclosed systems and methods relate to methods for benchmarking a quantum computing device by applying to the quantum computing device a sequence of quantum gates that can be simulated in polynomial time. The result of applying the sequence can be measured. A classical simulation can determine the probability of obtaining this result. The probability can be used to determine a fidelity measure for the quantum device.

The disclosed embodiments include a method of benchmarking a quantum device. The method can include selecting a sequence of M quantum gates from a group of quantum gates according to a probability distribution. The quantum gates in the group can be capable of polynomial-time classical simulation. The method can include obtaining an outcome measure by applying the sequence of M quantum gates to N qubits of a quantum computing device. The method can include obtaining, by polynomial-time classical simulation, a probability of obtaining the outcome value given the application of the selected sequence of M quantum gates. The method can include generating an averaged probability using the obtained probability and second probabilities obtained by applying to the N qubits second sequences of M quantum gates selected from the group. The method can include providing a fidelity benchmark for the M quantum gates based at least in part on the obtained probability.

In some embodiments, providing the fidelity benchmark can include dividing by M a function of the averaged probability, the quotient being the fidelity benchmark. In some embodiments, providing the fidelity benchmark can include determining, based in part on the averaged probability value, a fidelity function, an exponential decay coefficient of the fidelity function being the fidelity benchmark. In some embodiments, the group of quantum gates comprises a group of Clifford gates. In some embodiments, the N qubits comprise superconducting circuit, trapped ion, or photonic qubits. In some embodiments, N is greater than 100 or M is greater than 20. In some embodiments, the N qubits include a transmon or fluxonium qubit.

The disclosed embodiments include a system for benchmarking a quantum device. The system can include at least one processor and at least one non-transitory, computer-readable medium. The medium can contain instructions that, when executed by the at least one processor, cause the system to perform operations. The operations can include obtaining a sequence of M quantum gates from a group of quantum gates according to a probability distribution. The quantum gates in the group can be capable of polynomial-time classical simulation. The operations can include obtaining an outcome measure by applying the sequence of M quantum gates to N qubits of a quantum computing device. The operations can include obtaining, by polynomial-time classical simulation, a probability of obtaining the outcome value given the application of the selected sequence of quantum gates. The operations can include generating an averaged probability using the obtained probability and second probabilities obtained by applying to the N qubits second sequences of M quantum gates selected from the group. The operations can include providing a fidelity benchmark for the M quantum gates based at least in part on the obtained probability.

In some embodiments, providing the fidelity benchmark can include dividing by M a function of the averaged probability, the quotient being the fidelity benchmark. In some embodiments, providing the fidelity benchmark can include determining, based in part on the averaged probability value, an exponential decay coefficient, the exponential decay coefficient being the fidelity benchmark. In some embodiments, the group of quantum gates can include a group of Clifford gates. In some embodiments, the N qubits can include superconducting circuit, trapped ion, or photonic qubits. In some embodiments, N can be greater than 100 or M can be greater than 20. In some embodiments, the N qubits include a transmon or fluxonium qubit.

The disclosed embodiments include a computer-readable medium containing instructions. When executed by at least one processor, the instructions can cause a system to perform operations. The operations can include obtaining a sequence of M quantum gates from a group of quantum gates according to a probability distribution. The quantum gates in the group can be capable of polynomial-time classical simulation. The operations can include obtaining an outcome measure by applying the sequence of M quantum gates to N qubits of a quantum computing device. The operations can include obtaining, by polynomial-time classical simulation, a probability of obtaining the outcome value given the application of the selected sequence of quantum gates. The operations can include generating an averaged probability using the obtained probability and second probabilities obtained by applying to the N qubits second sequences of M quantum gates selected from the group. The operations can include providing a fidelity benchmark for the M quantum gates based at least in part on the obtained probability.

In some embodiments, providing the fidelity benchmark can include dividing by M a function of the averaged probability, the quotient being the fidelity benchmark. In some embodiments, providing the fidelity benchmark can include determining, based in part on the averaged probability value, an exponential decay coefficient, the exponential decay coefficient being the fidelity benchmark. In some embodiments, the group of quantum gates can include a group of Clifford gates. In some embodiments, the N qubits can include superconducting circuit, trapped ion, or photonic qubits. In some embodiments, N can be greater than 100 or M can be greater than 20. In some embodiments, the N qubits include a transmon or fluxonium qubit.

It is to be understood that both the foregoing general description and the following detailed description are exemplary and explanatory only and are not restrictive of the disclosed embodiments, as claimed.

### BRIEF DESCRIPTION OF THE DRAWINGS

The accompanying drawings, which comprise a part of this specification, illustrate several embodiments and, together with the description, serve to explain the principles and features of the disclosed embodiments. In the drawings:

FIG. 1 depicts an exemplary PXEB trial, in accordance with disclosed embodiments. in accordance with disclosed embodiments.

FIG. 2 depicts a system for performing PXEB, in accordance with disclosed embodiments, in accordance with disclosed embodiments.

FIG. 3 depicts an exemplary method for performing PXEB, in accordance with disclosed embodiments.

FIG. 4 depicts the results of simulated PXEB benchmarking using Clifford gates for a simulated 54 qubit quantum computing device, in accordance with disclosed embodiments.

### DETAILED DESCRIPTION

Reference will now be made in detail to exemplary embodiments, discussed with regards to the accompanying drawings. In some instances, the same reference numbers will be used throughout the drawings and the following description to refer to the same or like parts. Unless otherwise defined, technical or scientific terms have the meaning commonly understood by one of ordinary skill in the art. The disclosed embodiments are described in sufficient detail to enable those skilled in the art to practice the disclosed embodiments. It is to be understood that other embodiments may be utilized and that changes may be made without departing from the scope of the disclosed embodiments. Thus, the materials, methods, and examples are illustrative only and are not intended to be necessarily limiting.

Performance characterization is an important part of the development and validation of quantum computing devices. Performance characterization can be achieved through benchmarking of a quantum computing device, a set of gates on the quantum computing device, or a particular implementation of the set of gates on the quantum computing device. An efficient and reliable benchmarking scheme can enable comparison between different quantum computing devices (e.g., produced by different manufacturers) and can also provide useful feedback information that facilitates device calibration and error diagnosis. Accordingly, such benchmarking can support development of future hardware designs and of fault-tolerant quantum computing.

Conventional XEB has been used in a purported demonstration of quantum supremacy (e.g., performance of a task by a quantum computing system that cannot be performed using a classical computing system). According to this method, a sequence of M gates is applied to a quantum computing device. The state of the quantum computing device is then measured. The probability of obtaining the measured output is then obtained using classical simulation of the qubits (e.g., using a classical computer configured to perform digital operations using binary bit values). For example, a quantum computation can be represented as a tensor network and simulated using tensor network contractions, as described in “Efficient parallelization of tensor network contraction for simulating quantum computation.” Nature Computational Science 1.9 (2021): 578-587. The classical simulation techniques disclosed in this journal article are incorporated by reference herein. Multiple trials can be conducted for a sequence length m, and the simulated probably for each trial can be averaged to obtain a fidelity benchmark. The fidelity benchmark can be transformed into a value ranging between zero and one.

The limitations of conventional XEB make it particularly suitable for demonstrating quantum supremacy. Such a demonstration can involve applying quantum circuits to a quantum device. Some of the quantum circuits can include relatively few gates or be applied to relatively few qubits, enabling classical simulation of such quantum circuits. Conventional XEB can use such classical simulation to show that the quantum device behaves reliably for these shallow, small quantum circuits. The reliability of the quantum device when shallow, small quantum circuits are applied can support an inference that the quantum device behaves reliably when deep or large quantum circuits are applied, even though such quantum circuits cannot practicably be classically simulated (and therefore cannot be benchmarked using conventional XEB).

In this manner, conventional XEB using shallow, small quantum circuits can demonstrate the fidelity of the quantum device, while the impracticably of conventional XEB using deep, large quantum circuits can demonstrate quantum supremacy.

Unfortunately, the behavior of larger and deeper quantum circuits may differ from the behavior of smaller, shallower quantum circuits. An inference of fidelity drawn from the behavior of a quantum device on smaller, shallower circuits cannot replace a direct measurement of the fidelity of the quantum device on larger, deeper circuits. And such direct measurements cannot be obtained using conventional XEB.

As disclosed herein and appreciated by the inventors, conventional XEB can be converted from a tool for demonstrating quantum supremacy into a tool for benchmarking deep or large quantum circuits. Consistent with disclosed embodiments, a polynomial-time method of XEB (PXEB) can use gates suitable for classical simulation, such as Clifford gates or matchgates. This restriction ensures that deep or large quantum circuits can be classically simulated in polynomial time, enabling use of PXEB for such circuits (and therefore supporting a more comprehensive understanding of the performance of a quantum device). However, this restriction also renders PXEB unsuitable for demonstrating quantum supremacy.

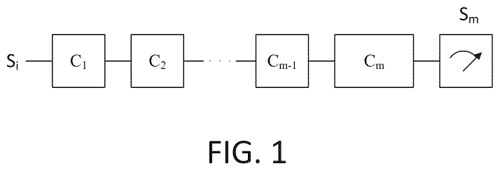

FIG. 1 depicts an exemplary PXEB trial, in accordance with disclosed embodiments. In such a trial, a particular sequence of M gates can be randomly selected according to a probability distribution (e.g., a uniform probability distribution) from a group of gates. The group of gates can consist of gates that can be classically simulated in polynomial time. In some embodiments, the gates can be Clifford gates. In various embodiments, the gates can be matchgates. A quantum computing device can be initialized to a particular state (e.g., state Sᵢ) and the particular sequence C of random gates can be applied. The state of the quantum computing device can then be measured (e.g., yielding measurement state Sₘ). The ideal probability \hat{p}(Sₘ) of obtaining state Sₘ given the application of sequence C and the initial state Sᵢ can be estimated:

\hat{p}(Sₘ)=| [symbol] Sₘ|C|Sᵢ [symbol] |²

Consistent with disclosed embodiments, calculated ideal probabilities \hat{p}ₖ(Sₘ) can be averaged for multiple trials 1 to k, forming an estimate \hat{p̅}, which can be used to compute a fidelity benchmark. In some embodiments, the fidelity value can be F(m)=2ⁿ\hat{p̅}−1, where N is the number of qubits. Multiple sets of trials can be performed for different sequence lengths, generating a set of fidelity values. An exponential curve can be fit to this set of fidelity values with respect to m. The exponentiated base of this curve can be provided as a fidelity benchmark of the quantum computing device.

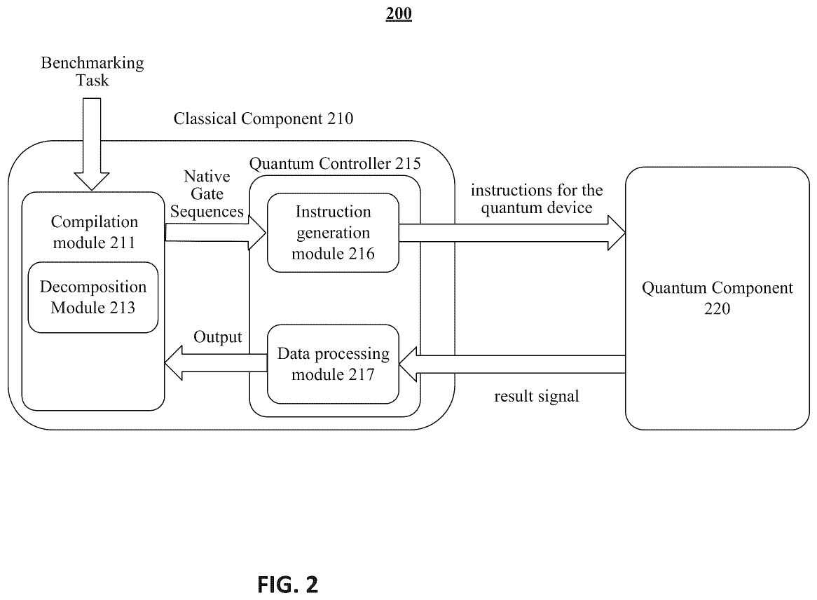

FIG. 2 depicts a system 200 for performing PXEB, in accordance with disclosed embodiments. The system 200 can include a classical component 210 (e.g., a classical computing device, or collection of classical computing devices) and a quantum component 220.

Quantum component 220 can be configured to process information using quantum phenomena (e.g., superposition or entanglement). Quantum component 220 can operate on units of information referred to as “qubits.” A qubit is the smallest unit of information in quantum computers, and can have any linear combination of two values, usually denoted |0 [symbol] and |1 [symbol] . The value of the qubit can be denoted |ψ [symbol] . Different from a digital bit that can have a value of either “0” or “1,” |ψ [symbol] can have a value of α|0 [symbol] +β|1 [symbol] where α and β are complex numbers (referred to as “amplitudes”) not limited by any constraint except |α|²+|β|²=1. Quantum states of components of quantum component 220 can represent qubits. The disclosed embodiments are not limited to any particular qubit implementation. For example, a qubit can be physically implemented using photons (e.g., in lasers) with their polarizations as the quantum states, electrons or ions (e.g., trapped in an electromagnetic field) with their spins as the quantum states, Josephson junctions (e.g., in a superconducting quantum system) with their charges, current fluxes, or phases as the quantum states, quantum dots (e.g., in semiconductor structures) with their dot spin as the quantum states, topological quantum systems, or any other system that can provide two or more quantum states. Quantum component 220 can apply quantum logic gates (or simply “quantum gates”) to create, remove, or modify qubits.

In contrast, classical component 210 can be computing system that cannot perform quantum computations, such as an electronic computer (e.g., a laptop, desktop, cluster, cloud computing platform, or the like). Classical component 210 can operate in digital logic on binary-valued bits. Classical component 210 can include one or more processors (e.g., CPUs, GPUs, or the like), application specific integrated circuits, hardware accelerators, or other components for processing digital logic. Classical component 210 can include one or more memories, buffers, caches, or other components for storing binary values. Classical component 210 can include one or more I/O devices of communicating with other systems, devices (e.g., quantum component 220), users, or the like.

The classical component 210 can be configured to control the quantum component 220. The classical component can include a compilation module 211. Compilation module 211 can be configured to obtain a description of a benchmarking task (e.g., an PXEB benchmarking task of quantum component 220). The description of the benchmarking task can include a description of the group of gates for use in benchmarking.

Based on the description of the benchmarking task, compilation module 211 can determine gate sequences for PXEB benchmarking. In some embodiments, compilation module 211 can determine sets of gate sequences for different sequence lengths m.

As may be appreciated, quantum component 220 can be designed to implement the group of quantum gates using a set of native gates. Gate decomposition module 213 (which may be implemented as a submodule of compilation module 211) can be configured to decompose the gate sequences determined by compilation module 211 into sequences of native gates that can be physically implemented on quantum component 220. The sequences of native gates can then be provided to quantum controller 215.

Quantum controller 215 can be configured to directly control quantum component 220. Quantum controller 215 can be a digital computing device (e.g., a computing device including a central processing unit, graphical processing unit, application specific integrated circuit, field-programmable gate array, or other suitable processor). Quantum controller 215 can configure quantum component 220 for computation, provide quantum gates to, and read state information out of quantum component 220.

Quantum controller 215 can include an instruction generation module 216. The capabilities of instruction generation module 216 can depend on the particular implementation of quantum component 220. In some embodiments, instruction generation module 216 can be configured to directly or indirectly provide bias drives to quantum component 220 to enable or disable interactions between qubits. Instruction generation module 216 can indirectly provide bias drives by providing instructions to a bias drive source (e.g., waveform generator or the like), causing the bias drive source to provide the bias drives to quantum component 220. Instruction generation module 216 can apply native quantum gates by providing one or more microwave pulses (or other gate drives) to qubits in quantum component 220. In various embodiments, instruction generation module 216 can implement such gates by providing instructions to a computation drive source (e.g., a waveform generator or the like), causing the computational drive source to provide such microwave pulses (or other gate drives) to qubits in quantum component 220. The microwave pulses can be selected or configured to implement one or more native quantum gates, as described herein. The microwave pulses can be provided to qubits using one or more coils coupled to the corresponding qubits. The coils can be external to quantum component 220 or on a chip implementing quantum component 220.

Quantum controller 215 can be configured to determine state information for quantum component 220. In some embodiments, quantum controller 215 can measure a state of one or more qubits of quantum component 220. The state can be measured upon completion of a sequence of one or more quantum operations. In some embodiments, instruction generation module 216 can provide a probe signal (e.g., a microwave probe tone) to a coupled resonator of quantum component 220, or provide instructions to a readout device (e.g., an arbitrary waveform generator) that provides the probe signal.

In various embodiments, quantum controller 215 can include a data processing module 217. The capabilities of data processing module 217 can depend on the particular implementation of quantum component 220. In some embodiments, data processing module 217 can take the output signal (e.g., electrical/photonic), transform it into discrete signals, and perform data processing on it (e.g., averaging, post-processing) to obtain a computational result. In some embodiments, data processing module 217 can include, or be configured to receive information from, a detector configured to determine an amplitude and phase of an output signal received from the coupled resonator in response to provision of the microwave probe tone. The amplitude and phase of the output signal can be used to determine the state of the probed qubit(s). The disclosed embodiment are not limited to any particular method of measuring the state of the qubits.

Consistent with disclosed embodiments, quantum controller 215 can be configured to provide output to compilation module 211 (or another suitable module of classical component 210).

Consistent with disclosed embodiments, classical component 210 (e.g., compilation module 211 or another suitable module of classical component 210) or another system, can be configured to use the output in determining a fidelity benchmark for quantum component 220. In some embodiments, classical component 210 can be configured to determine an ideal probability of measuring the output, given in the initial state of quantum component 220 and the sequence of applied gates. Classical component 210 can be configured to determine an average ideal probability for sequences of length m, based on ideal probabilities obtained from multiple trials. Classical component 210 can be configured to determine a fidelity value for sequences of length M based on the average ideal probability and the number of qubits to which the sequences of gates were applied. Classical component 210 can be configured to determine the fidelity benchmark based on fidelity values for differing sequence lengths.

Consistent with disclosed embodiments, when classical component 210 determines the fidelity benchmark for quantum component 220, classical component 210 can be configured to provide that fidelity benchmark to a user (e.g., using a graphical user interface, or the like), to another system, or to a storage location accessible to classical component 210.

Quantum component 220 can be configured to receive commands (e.g., bias drives, quantum gates, probe signal, or the like) from the classical component 210. In some embodiments, quantum component 220 can be implemented using a superconducting quantum circuit coupled to quantum controller 215 using at least one microwave drive line. The superconducting quantum circuit can implement multiple qubits (e.g., transmon qubits, fluxonium qubits, or any other suitable type of qubit), consistent with disclosed embodiments. In some embodiments, the superconducting quantum circuit can be realized using one or more chips containing the qubits, each of the chip(s) including at least a portion of the microwave drive line(s) coupling the qubit(s) to quantum controller 215.

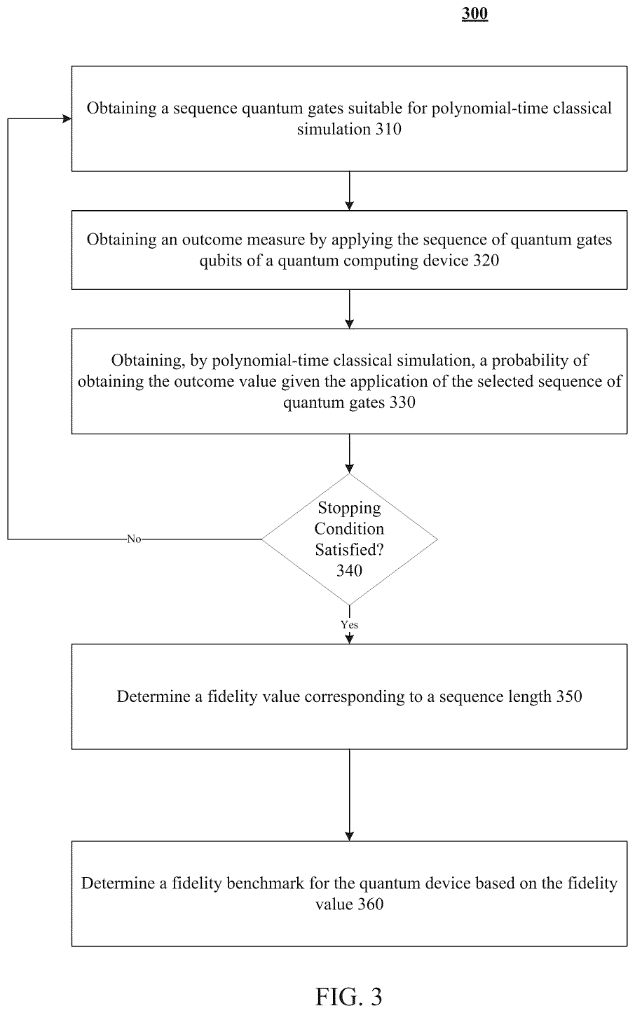

FIG. 3 depicts an exemplary method 300 for performing PXEB, in accordance with disclosed embodiments. In some embodiments, method 300 can be performed using system 200. Method 300 can include operations performed on a conventional computing device (e.g., a mobile device, laptop, desktop, workstation, computing cluster, cloud-computing platform, or the like) such as classical component 210. Method 300 can include operations performed on a quantum computing device (e.g., a quantum controller managing a superconducting circuit, trapped ion quantum systems, topological quantum computing systems, photonic quantum computing systems, or the like) such as quantum component 220.

Consistent with disclosed embodiments, the conventional computing device can be configured to apply gate sequences to the quantum computing device. The conventional computing device can also be configured to measure the state of the quantum computing device following application of each gate sequence. In some embodiments, the conventional computing device can be configured to determine a probability of obtaining the measured state of the quantum computing device, given the initial state of the quantum computing device and the applied gate sequence. In some embodiments, the conventional computing device can be configured to determine a fidelity value for gate sequences of length m. In some embodiments, the conventional computing device can be configured to determine a fidelity benchmark based on fidelity values for gate sequences of multiple lengths.

Prior to performance of method 300, a group of gates can be selected. The select group of gates can consist of gates that can be classically simulated in polynomial time. For example, the group can include Clifford gates or can include matchgates. In some embodiments, the conventional computing device can be configured to select the group of gates. In some embodiments, the conventional computing device can be configured with a predetermined group of gates. In various embodiments, the conventional computing device can receive or retrieve an indication of the group of gates (e.g., from another system or through interactions with a user).

In step 310, the conventional computing device can obtain a sequence of M quantum gates suitable for polynomial-time classical simulation, in accordance with disclosed embodiments. In some embodiments, the conventional computing device can receive or retrieve the sequence from another computing device. In various embodiments, the conventional computing device can generate the sequence. For example, the conventional computing device can independently draw M gates from the group of gates according to a probability distribution. The probability distribution can be a uniform probability distribution over the group of gates.

As may be appreciated, because the gates can be classically simulated, the sequence length M can be substantially larger than can be achieved using conventional XEB. For example, the depth of the sequence can be greater than 20 gates, greater than 50 gates, greater than 100 gates, greater than 200 gates, greater than 500 gates, greater than 1000 gates, or more.

In step 320, the conventional computing device can obtain an outcome measure by applying the sequence of quantum gates to N qubits of a quantum computing device, in accordance with disclosed embodiments. In some embodiments, the conventional computing device initialize the quantum computing device. The conventional computing device can then apply the selected sequence of quantum gates to the quantum computing device. As may be appreciated, the quantum computing device may have a set of native quantum gates. Applying the sequence of quantum gates can include converting the sequence to an equivalent sequence of the native quantum gates and applying the equivalent sequence of the native quantum gates. In some embodiments, applying the sequence of quantum gates can include providing instructions to the quantum computing device to apply the sequence of quantum gates. Consistent with disclosed embodiments, after applying the sequence of gates, the conventional computing device can then measure (or provide instructions to measure) the state of the quantum computing device.

As may be appreciated, because the gates can be classically simulated, the sequence can be applied to a substantially larger number of qubits than could be benchmarked using conventional XEB. For example, N can be greater than 100 qubits, greater than 200 qubits, greater than 500 qubits, greater than 1000 qubits, or more. Thus the disclosed embodiments enable the benchmarking of (and therefore support the development of) more complex (and thus potentially more useful) quantum circuits .

In step 330, the conventional computing device (or another device) can determine an ideal probability of obtaining the measured state of the quantum system. This ideal probability can be determined through classical simulation. Suitable simulation programs include the simulator disclosed in “Stim: a fast stabilizer circuit simulator” Quantum 5, 497 (2021). The disclosure of this simulation program is incorporated herein by reference.

In step 340, the conventional computing device can determine whether a stopping condition is satisfied. If the stopping condition is not satisfied, method 300 can return to step 310 and another ideal probability can be estimated. Such estimation can include drawing another, independent gate sequence of length M and applying this gate sequence to the quantum computing device. If the stopping condition is satisfied, method 300 can proceed to step 350.

The stopping condition can depend on time, a number of ideal probabilities generated, a statistical criterion, or any combination of the foregoing. For example, the conventional computing device can determine that the stopping condition is satisfied when an elapsed benchmarking time exceeds a predetermined time threshold. As an additional example, the conventional computing device can determine that the stopping condition is satisfied upon determination of a threshold number of ideal probabilities. In some embodiments, the conventional computing device can determine that the stopping condition is satisfied based on a standard deviation, confidence interval, interval estimate, standard error of the mean, or other statistical value. The statistical value can be calculated over a set of ideal probabilities for sequences of length m. For example, the stopping condition can be satisfied when a standard deviation or standard error of the mean for a set of such ideal probabilities is less than a predetermined value.

In step 350, the computing device can be configured to determine a fidelity value corresponding a sequence length (e.g., the sequence length M of step 310 and 320), in accordance with disclosed embodiments. In some embodiments, this determination can include generating an averaged probability. The averaged probability can be generated using previously obtained ideal probabilities for sequences of length M (e.g., the ideal probability obtained in step 330, one or more ideal probabilities obtained in previous iterations of steps 310 to 330, or the like). As described above with regards to FIG. 1, in some embodiments, the fidelity value corresponding to length M can be F(m)=2ⁿ\hat{\vec{p}}−1, where N is the number of qubits in the quantum device, and \hat{\vec{p}} is the averaged probability.

In step 360, the computing device can be configured to determine a fidelity benchmark for the quantum device based on the fidelity value, in accordance with disclosed embodiments. In some embodiments, the fidelity benchmark can depend on multiple fidelity values. For example, a function can be fit to a set of fidelity values calculated for differing sequence lengths. The fidelity benchmark can be a parameter of the fitted function. For example, an exponential function can be fit to the set of fidelity values. The exponentiated base of the exponential function could then be the fidelity benchmark.

In various embodiments, the fidelity benchmark can depend on a single fidelity value. In some embodiments, the fidelity benchmark can be the experimentally obtained fidelity value scaled by an ideal fidelity value. For example, given ideal gates (e.g., gates having a gate error rate of zero), \hat{\vec{p}}→1 as M decreases and \hat{\vec{p}}→2⁻⁽ⁿ⁻¹⁾ as m→∞. Thus, for such ideal gates, F(m)→2ⁿ−1 as M decreases and F(m)→1 as m→∞. The value of F(m) for an ideal gate forms an upper bound on values for F(m). An experimentally obtained value of F(m) can therefore be scaled by a theoretical value of F(m) for ideal gates to obtain a fidelity benchmark having a value on the interval [0, 1]. In some embodiments, the m^{th} root of this fidelity benchmark can be calculated to obtain a fidelity benchmark for a single gate.

As may be appreciated, method 300 may return to step 310 after step 350 when the fidelity benchmark depends upon multiple fidelity values (not shown in FIG. 3). The determination of whether to proceed to step 360 or return to step 310 may depend on satisfaction of a stopping condition. Similar to the stopping condition in step 340, this stopping condition can depend upon time, a number of fidelity values generated, a statistical criterion, or any combination of the foregoing. In such embodiments, the statistical criterion can be an estimate of the goodness-of-fit of a function fitted to the experimentally obtained fidelity values.

The disclosed embodiments are not limited to embodiments in which a single conventional computing device obtains the sequence of quantum gates, applies the sequence to the quantum computing device, obtains the outcome measure, determines the fidelity value, and determines the fidelity benchmark. In various embodiments, these operations can be performed by multiple computing devices. For example, a first conventional computing device can obtain the sequence of quantum gates, determine the fidelity measure, and determine the fidelity benchmark. A second conventional computing device can apply the sequence of quantum gates to the quantum computing device and obtain the outcome measure.

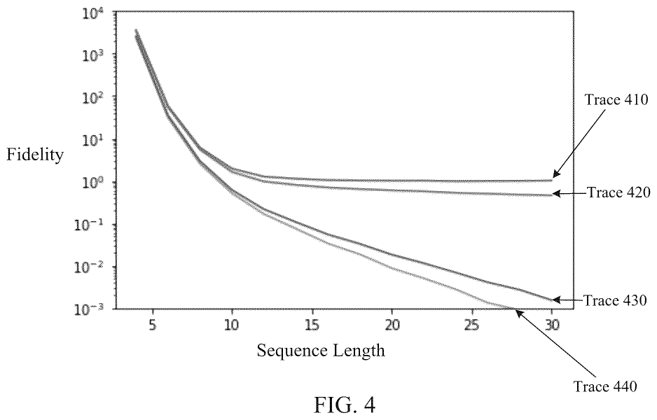

FIG. 4 depicts the results of simulated PXEB benchmarking using Clifford gates for a simulated 54 qubit quantum computing device, in accordance with disclosed embodiments. In this semi log plot, the x axis is the sequence length, and the y axis is the corresponding fidelity value. The depicted traces correspond to differing two-qubit gate error rates. The simulated PXEB benchmarking used gate sequences including up to 30 gates. Simulating the behaviors of such deep and large quantum circuits was practicable because Clifford gates can be simulated in polynomial time. Furthermore, the demonstrated practicability of simulated PXEB benchmarking validates the practicability of actual PXEB benchmarking for quantum circuits of similar depth and size.

Trace 410 depicts the result of simulated PXEB benchmarking of ideal quantum gates having zero two-qubit gate error. For such ideal gates, F(m)→2ⁿ−1 as M decreases and F(m)→1 as m →∞. Trace 420 depicts the result of simulated PXEB benchmarking of quantum gates having a gate error of 0.1%. Trace 430 depicts the result of simulated PXEB benchmarking of quantum gates having a gate error of 0.7%. Trace 440 depicts the result of simulated PXEB benchmarking of quantum gates having a gate error of 1%. While trace 420 exhibits a marked decrease in fidelity value as gate sequence length increases, the decrease is far less than the decreases exhibited by trace 430 and trace 440.

In some embodiments, a non-transitory computer-readable storage medium including instructions is also provided, and the instructions may be executed by a device (such as the disclosed encoder and decoder), for performing the above-described methods. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM or any other flash memory, NVRAM, a cache, a register, any other memory chip or cartridge, and networked versions of the same. The device may include one or more processors (CPUs), an input/output interface, a network interface, and/or a memory.

The foregoing descriptions have been presented for purposes of illustration. They are not exhaustive and are not limited to precise forms or embodiments disclosed. Modifications and adaptations of the embodiments will be apparent from consideration of the specification and practice of the disclosed embodiments. For example, the described implementations include hardware, but systems and methods consistent with the present disclosure can be implemented with hardware and software. In addition, while certain components have been described as being coupled to one another, such components may be integrated with one another or distributed in any suitable fashion.

Moreover, while illustrative embodiments have been described herein, the scope includes any and all embodiments having equivalent gates, modifications, omissions, combinations (e.g., of aspects across various embodiments), adaptations or alterations based on the present disclosure. The gates in the claims are to be interpreted broadly based on the language employed in the claims and not limited to examples described in the present specification or during the prosecution of the application, which examples are to be construed as nonexclusive. Further, the steps of the disclosed methods can be modified in any manner, including reordering steps or inserting or deleting steps.

It should be noted that, the relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

The features and advantages of the disclosure are apparent from the detailed specification, and thus, it is intended that the appended claims cover all systems and methods falling within the true spirit and scope of the disclosure. As used herein, the indefinite articles “a” and “an” mean “one or more.” Further, since numerous modifications and variations will readily occur from studying the present disclosure, it is not desired to limit the disclosure to the exact construction and operation illustrated and described, and accordingly, all suitable modifications and equivalents may be resorted to, falling within the scope of the disclosure.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

It is appreciated that the above-described embodiments can be implemented by hardware, or software (program codes), or a combination of hardware and software. If implemented by software, it may be stored in the above-described computer-readable media. The software, when executed by the processor can perform the disclosed methods. The computing units and other functional units described in this disclosure can be implemented by hardware, or software, or a combination of hardware and software. One of ordinary skill in the art will also understand that multiple ones of the above-described modules/units may be combined as one module/unit, and each of the above-described modules/units may be further divided into a plurality of sub-modules/sub-units.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation or restriction of the scope of the embodiments, the scope being defined by the following claims.

What is claimed is:

1. A method of benchmarking a quantum device comprising:
selecting a sequence of M quantum gates from a group of quantum gates according to a probability distribution, the quantum gates in the group being capable of polynomial-time classical simulation;
obtaining an outcome value by applying the sequence of M quantum gates to N qubits of a quantum computing device;
obtaining, by polynomial-time classical simulation, a probability of obtaining the outcome value given the application of the selected sequence of M quantum gates;
generating an averaged probability using the obtained probability and second probabilities obtained by applying to the N qubits second sequences of M quantum gates selected from the group; and
providing a fidelity benchmark for the M quantum gates based at least in part on the obtained probability.

2. The method of claim 1, wherein:
providing the fidelity benchmark comprises:
dividing by M a function of the averaged probability, the quotient being the fidelity benchmark.

3. The method of claim 1, wherein:
providing the fidelity benchmark comprises:
determining, based in part on the averaged probability, a fidelity function, an exponential decay coefficient of the fidelity function being the fidelity benchmark.

4. The method of claim 1, wherein:
the group of quantum gates comprises a group of Clifford gates.

5. The method of claim 1, wherein:
the N qubits comprise superconducting circuit, trapped ion, or photonic qubits.

6. The method of claim 1, wherein:
N is greater than 100.

7. The method of claim 1, wherein:
M is greater than 20.

8. The method of claim 1, wherein the N qubits comprise a transmon or fluxonium qubit.

9. A system for benchmarking a quantum device comprising:
at least one processor; and
at least one non-transitory, computer-readable medium containing instructions that, when executed by the at least one processor, cause the system to perform operations comprising:
obtaining a sequence of M quantum gates from a group of quantum gates according to a probability distribution, the quantum gates in the group being capable of polynomial-time classical simulation;
obtaining an outcome value by applying the sequence of M quantum gates to N qubits of a quantum computing device;
obtaining, by polynomial-time classical simulation, a probability of obtaining the outcome value given the application of the selected sequence of M quantum gates;
generating an averaged probability using the obtained probability and second probabilities obtained by applying to the N qubits second sequences of M quantum gates selected from the group; and
providing a fidelity benchmark for the M quantum gates based at least in part on the obtained probability.

10. The system of claim 9, wherein:
providing the fidelity benchmark comprises:
dividing by M a function of the averaged probability, the quotient being the fidelity benchmark.

11. The system of claim 9, wherein:
providing the fidelity benchmark comprises:
determining, based in part on the averaged probability, an exponential decay coefficient, the exponential decay coefficient being the fidelity benchmark.

12. The system of claim 9, wherein:
the group of quantum gates comprises a group of Clifford gates.

13. The system of claim 9, wherein:
the N qubits comprise superconducting circuit, trapped ion, or photonic qubits.

14. The system of claim 9, wherein:
N is greater than 100.

15. The system of claim 9, wherein:
M is greater than 20.

16. The system of claim 9, wherein the N qubits comprise a transmon or fluxonium qubit.

17. A computer-readable medium containing instructions that are executable by at least one processor of a system to cause the system to perform operations comprising:
obtaining a sequence of M quantum gates from a group of quantum gates according to a probability distribution, the quantum gates in the group being capable of polynomial-time classical simulation;
obtaining an outcome value by applying the sequence of M quantum gates to N qubits of a quantum computing device;
obtaining, by polynomial-time classical simulation, a probability of obtaining the outcome value given the application of the selected sequence of M quantum gates;
generating an averaged probability using the obtained probability and second probabilities obtained by applying to the N qubits second sequences of M quantum gates selected from the group; and
providing a fidelity benchmark for the M quantum gates based at least in part on the obtained probability.

18. The medium of claim 17, wherein:
providing the fidelity benchmark comprises:
dividing by M a function of the averaged probability, the quotient being the fidelity benchmark.

19. The medium of claim 17, wherein:
providing the fidelity benchmark comprises:
determining, based in part on the averaged probability, an exponential decay coefficient, the exponential decay coefficient being the fidelity benchmark.

20. The medium of claim 17, wherein:
the group of quantum gates comprises a group of Clifford gates.

21. The medium of claim 17, wherein:
the N qubits comprise superconducting circuit, trapped ion, or photonic qubits.

22. The medium of claim 17, wherein:
N is greater than 100 or M is greater than 20.

23. The medium of claim 17, wherein the N qubits comprise a transmon or fluxonium qubit.
